(19) United States
(12) Patent Application Publication
(10) Pub. No.: US 2012/0225319 A1
(43) Pub. Date: Sep. 6, 2012

(54) COATED INSULATING FILMS FOR ELECTRIC MACHINES AND MANUFACTURING PROCESS THEREFOR

(76) Inventor: Christian Seidel, Schwaig (DE)

(21) Appl. No.: 13/509,198

(22) PCT Filed: Oct. 29, 2011
(86) PCT No.: PCT/EP2010/066492

§ 371 Date: May 10, 2012

(30) Foreign Application Priority Data
Nov. 10, 2009 (DE) 102009052432.0

(51) Int. Cl. B32B 27/00; C23C 16/513; B05D 3/00; C23C 16/44; B05D 3/04

(52) U.S. Cl. 428/688; 427/255.28; 427/248.1; 427/374.1; 427/569; 427/488

(57) ABSTRACT

A polymer film has a markedly improved resistance to erosion in the electrical field (so-called corona stability) when permanently subject to partial discharge.

### CROSS REFERENCE TO RELATED APPLICATIONS

This application is the U.S. national stage of International Application No. PCT/EP2010/066492, filed Oct. 29, 2010 and claims the benefit thereof. The International Application claims the benefits of German Application No. 102009052432.0 filed on Nov. 10, 2009, both applications are incorporated by reference herein in their entirety.

### BACKGROUND

Described below is a coated insulating film having increased corona resistance in the electrical field.

Electric machines (transformers, motors, generators) exhibit a complex insulation system depending on output and construction principle. Film materials are here used as insulation in different areas. These insulating film materials are thermoplastic or chemically crosslinked polymer films. A reasonable number of film materials are considered, which fulfill the mechanical, electrical and thermal requirements. In the case of motors and generators, corresponding films for the main and subconductor insulation are wound around the conductor.

Corona-stable PI films can be used for the subconductor insulation. These films are very expensive and are only offered by one manufacturer. Mica-coated surface insulation material can be used for the main insulation. This solution is also expensive and difficult in terms of handling. There is the risk during winding that the mica particles chip off. Polyethylene terephthalate (PET), polyethylene napththalate (PEN) and polyimide PI films are mainly used as polymer films, in other words as carriers for the mica particles.

The disadvantage with the known solutions is that the thus produced insulations are difficult to handle and expensive to produce. For instance, when winding around the conductor, minimal bending radii of the mica-coated films cannot be realized, because otherwise the mica chips off. Since after winding the insulating film is very generally impregnated with resin for mechanical stability, or, in the case of materials containing mica, is already used as a resin-impregnated half-finished product (so-called resin rich materials), there is the risk of damaged points in the resin impregnation, which reduce the corona resistance and thus compromise the durable reliability of the insulation, being produced in the case of insulations according to the related art.

### SUMMARY

It is therefore desirable to produce an insulation for electric machines, in particular transformers, motors, generators, which indicates an improved corona stability in the case of a well-insulated electric machine.

Accordingly, described below is an electrical surface insulation with high corona stability against erosion in the electrical field, which includes a polymer film as a carrier having a coating applied to one or both sides either partially or over the whole surface forming a close-mesh crosslinked inorganic or partially inorganic non-conducting material which is as a result difficult to transfer to the gas phase. In addition, described below is a method for producing the improved insulation by gas deposition or by way of wet-chemical methods.

In the present case “high corona resistance” is equated for instance to a local material removal of less than 250 μm, e.g., less than 150 μm, or less than 100 μm, in particular less than 50 μm of the insulating surface material below an electrode having a diameter of 6 mm with an E-field load of 6.5 V/μm for 240 hours. “Below” an electrode is understood to mean that the electrode rests directly thereupon, but without pressure.

“Cross-links” are referred to within the layer as the atomic centers, the chemical bond between two or more manufactured molecular parts, also known as monomer units.

These coatings are referred to as “materials which are difficult to transfer to the gas phase” because they exhibit a high resistance to material break-down or b-scission with the temperature load which occurs during the mica discharge (molecular mass degradation). There may also be used inorganic or hybrid inorganic materials, which are also referred to below as “partially inorganic”.

Inorganic is understood in this case to mean all atomic centers which do not contain carbonate.

“Close-mesh” is referred to here as the closer link between inorganic polymers compared with organic polymers.

Smaller bending radii can be realized by the described coating, which is compact and smooth, than is possible for instance with the mica-coated films. Also difficulties with the fault-free impregnation of the mica-coated films cannot occur with the described coated films, since the compact, smooth surface of the coating can be impregnated without any problem. This increases the reliability and durability of the insulation system during use. An improved wettability of the film with the resin by the coating furthermore boosts reliability.

The proposed coating of the polymer film significantly improves the resistance to erosion in the electrical field (so-called corona stability) when permanently subjected to partial discharge. This is inter alia attributed back to the inorganic or partially inorganic coating being crosslinked in a comparably close-mesh fashion and also being difficult to transfer to the gas phase.

According to an advantageous embodiment, the coating material is made of a high-melting inorganic material like a ceramic material e.g. a titanate or of a partially inorganic material, like the so-called non-metallic hybrid polymers. According to another embodiment, the inorganic material is for instance a nitride like the trisilicon tetranitride Si₃N₄ with a melting point of 1900° C. Phosphates or oxides can however also be used here advantageously. Particularly advantageous is aluminum oxide Al₂O₃ having a melting point of 2045° C. and SiOₓ, which has a melting point of the quartz modification β cristobalite (x=2) of 1705° C. in a close-mesh crosslinked modification. Further materials may be: silicon carbide (SiC), barium titanate (BaTiO3), silicon nitride (SiN) or derivatives of these materials as well as all other ceramic compounds.

Methods known per se are resorted to for the manufacture of the coating. In this way two methods are basically chosen, on the one hand the wet chemical method by way of the sol-gel coating method and on the other hand the deposition method from the gas phase, which are partially implemented using plasma methods.

These methods are all used to produce non-conducting, inorganic or partially inorganic coatings, which are close-mesh crosslinked and/or can otherwise be conveyed with difficulty into the gas phase. This increases the corona resistance.

The inorganic or partially inorganic non-conducting coatings can be applied to the polymer films for instance by way of low pressure PVD or low pressure CVD or atmospheric pressure plasma polymer coating methods.

Similarly, silane and siloxane can be applied to the polymer films as coatings by way of the sol-gel method, thereby forming a SiO backbone for instance, which is close-mesh crosslinked and thus fulfils the property that the coating can only be vaporized with difficulty. Silane, siloxane, organically modified silane and/or their mixtures are considered as prepolymers for the sol-gel synthesis. The properties of the sol-gel layers can be adjusted by setting the inorganic to organic portion by suitably selecting the prepolymers. Furthermore, layers can be realized which are based on interpenetrating networks of such sol-gel condensates and the organic polymers.

Several polymer films can be listed as suitable, for instance standard materials such as polyethylene (PE), polypropylene (PP), polyvinyl chloride (PVC), polyethylene terephthalate (PET) or polyethylene naphthalate (PEN), but other duroplastic and high-temperature-stable films such as polyimide (PI), polyetheretherketon (PEEK), polyetherimide (PEI), polyether sulphone (PES), liquid crystal polymer (LCP) etc. can be used.

The thickness of the layer can vary, for instance it can be less than 500 μm, in particular less than 100 μm and more particularly between 5 nm and 150 μm. It is apparent here that layers applied by wet chemical methods are significantly thicker than the layers applied by depositions in vacuum. The wet-chemically generated layers therefore move in the range of 0.1 to 150 μm, whereas the layers generated by deposition may indicate an effect in the range of 1 to 50 nm thick.

A significant improvement in the corona resistance of the films to electrical partial discharge can already be generated by very thin PVD or CVD coatings around 50 nm.

One possibility is coating by wet-chemical materials, which are applied in the sol-gel process. Also in this case, significant improvements can already be achieved by thin layers in the range of a few μm. Both the deposition from the gas phase and also the sol-gel coating can be effectively automated and therefore represent effectively scalable coating processes.

Expensive erosion-stable PI films or mica-coated films from PET or PEN for the sub or main conductor insulation can be replaced by these cost-effectively coated films. Furthermore, the handling of the films in a winding process may be considerably easier than for a mica particle-coated film, since on account of the compact coating, chipping off of the mica particles cannot occur. Smaller bending radii can also be realized.

The resin impregnation of the coated films is furthermore possible in a more reliable fashion than the through impregnation of the mica particles. A risk of the formation of service life-reducing defects as a result of defective through impregnation of the mica tape does not occur with the coated film. The compact and smooth coating, depending on the embodiment, generally even achieves an improved resin wetting compared with the uncoated film.

### BRIEF DESCRIPTION OF THE DRAWINGS

These and other aspects and advantages will become more apparent and more readily appreciated from the following description of the exemplary embodiments, taken in conjunction with the accompanying drawings: which:

The FIGURE is a side view of the structure of an exemplary embodiment of the film.

### DETAILED DESCRIPTION OF THE PREFERRED EMBODIMENT

Reference will now be made in detail to the preferred embodiments, examples of which are illustrated in the accompanying drawings, wherein like reference numerals refer to like elements throughout.

A polymer film 1 is visible centrally, which in the embodiment shown here is coated on both sides and not only on one side.

The coating 2 and 3 from close-mesh crosslinked inorganic or partially inorganic non-conducting material which is difficult to transfer to the gas phase is therefore on both sides of the film 1. This coating which is also referred to as “electrical barrier layer” has a higher rigidity and brittleness in comparison with the polymer film. As a result, the elongation at rupture of the polymer film is generally also reduced. In order to counteract this negative effect, in a particularly advantageous embodiment this is coated with an elastifying layer 4 or 5. All elastic polymer coating systems such as PU, epoxy resin, silicone and/or acrylates etc. are suitable herefor. In an advantageous embodiment, this elastifying equalizing layer has layer thicknesses in the range of 0.1 to 100 μm. It is advantageously wet-chemically applied in the roll-to-roll process by way of printing, doctor knife, immersion or other inline-compatible methods.

As described above, a coating of standard PET films with inorganic or partially inorganic layers such as SiOx, Al2O3, Si3N4 etc. which can be applied by way of low pressure PVD, low pressure CVD or atmospheric pressure plasma polymer coating methods, is initially disclosed, which simultaneously results in an increased corona stability of the film and an at least constant mechanical rigidity (also exposed to thermal ageing) as for the uncoated film.

The polymer film has resistance to erosion in the electrical field (so-called corona stability) that is significantly improved, compared to the known art, when permanently subjected to partial discharge. All non-metallic, non-conducting layers with a high crosslinking density and inorganic portions are in principle suited hereto. Similarly, the corona resistance can be significantly increased by highly crosslinked wet-chemical siloxane layers and/or all types of inorganic or hybrid polymer sol-gel layers.

A typical example of the increase in resistance of a 50 μm thick PET film coated with a sol-gel coating to electrical erosion by partial discharge can be shown visually.

A description has been provided with particular reference to preferred embodiments thereof and examples, but it will be understood that variations and modifications can be effected within the spirit and scope of the claims which may include the phrase “at least one of A, B and C” as an alternative expression that means one or more of A, B and C may be used, contrary to the holding in Superguide v. DIRECTV, 358 F3d 870, 69 USPQ2d 1865 (Fed. Cir. 2004).

1-7. (canceled)

8. An electrical surface insulation having high corona stability to erosion in an electrical field, comprising:
a polymer film as a carrier, having a coating applied at least partially on at least one surface, including a close-mesh crosslinked non-conducting material which is at least partially inorganic and as a result is difficult to transfer to gas phase.

9. The surface insulation as claimed in claim 8, wherein the polymer film is a duroplastic film.

10. The surface insulation as claimed in 9, wherein the polymer film is a thermoplastic film.

11. The surface insulation as claimed in claim 10, wherein the polymer film is an elastomer film.

12. The surface insulation as claimed in claim 11, further comprising an equalizing layer between the coating and the polymer film.

13. The surface insulation as claimed in claim 10, further comprising an equalizing layer between the coating and the polymer film.

14. The surface insulation as claimed in claim 9, wherein the polymer film is an elastomer film.

15. The surface insulation as claimed in claim 14, further comprising an equalizing layer between the coating and the polymer film.

16. The surface insulation as claimed in claim 9, further comprising an equalizing layer between the coating and the polymer film.

17. The surface insulation as claimed in 8, wherein the polymer film is a thermoplastic film.

18. The surface insulation as claimed in claim 17, wherein the polymer film is an elastomer film.

19. The surface insulation as claimed in claim 18, further comprising an equalizing layer between the coating and the polymer film.

20. The surface insulation as claimed in claim 8, wherein the polymer film is an elastomer film.

21. The surface insulation as claimed in claim 20, further comprising an equalizing layer between the coating and the polymer film.

22. The surface insulation as claimed in claim 8, further comprising an equalizing layer between the coating and the polymer film.

23. A method for manufacturing a surface insulation, comprising:
forming a coating on a polymer film, formed of a close-mesh crosslinked non-conducting material which is at least partially inorganic, by wet chemical deposition using one of a sol-gel method, chemical vapor deposition and physical vapor deposition.

24. The method as claimed in claim 23, wherein the wet chemical deposition is a plasma-assisted method and/or uses plasma polymerization.
